(19) United States
(12) Patent Application Publication
(10) Pub. No.: US 2009/0003501 A1
(43) Pub. Date: Jan. 1, 2009

(54) Offset Error Mitigation in a Phase-Locked Loop Circuit with a Digital Loop Filter

(76) Inventors: Gunter Steinbach, Palo Alto, CA (US); John Patrick Keane, Menlo Park, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/771,540

(22) Filed: Jun. 29, 2007

(51) Int. Cl. H03D 3/24

(52) U.S. Cl. 375/376

(57) ABSTRACT

A phase-locked loop circuit comprises an analog section, a digital section and a digital offset mitigation circuit. The analog section is subject to offset error and comprises an analog phase comparator and an analog-to-digital converter. The digital section comprises a digital loop filter and a digitally-controlled frequency-generating circuit. The digital loop filter is connected to receive a digital difference signal from the analog-to-digital converter. The digital offset mitigation circuit is operable in response to the digital difference signal to mitigate the offset error of the analog section.

### BACKGROUND

Phase-locked loop circuits are used in many applications, such as clock and data recovery, to lock a locally-generated clock signal in phase to an input signal. FIG. 1A is a block diagram showing an example of a conventional phase-locked loop circuit 10. Phase-locked loop circuit 10 is composed of a phase detector 12, a loop filter 16 and a controlled oscillator 18 connected in series. Phase detector 12 is connected to receive an input signal IN at one input and a feedback signal FB at the other input. Feedback signal FB is derived from the output signal OUT generated by controlled oscillator 18. Phase detector 12 generates a difference signal DS that represents the phase difference between feedback signal FB and input signal IN. Loop filter 16 filters difference signal DS to generate a control signal CS that controls the frequency of controlled oscillator 18 and, hence the frequency of output signal OUT. Phase-locked loop circuit 10 operates to minimize the difference in phase between input signal IN and feedback signal FB derived from output signal OUT.

FIG. 1B is a block diagram showing an example of another type of conventional phase-locked loop circuit 20 known as a delay-locked loop circuit. Delay-locked loop circuit 20 is composed of phase detector 12, loop filter 16, an integrator 22 and a controlled phase shifter 28 connected in series. Phase detector 12 is connected to receive input signal IN at one input and a feedback signal FB at the other input. Feedback signal FB is derived from the output signal OUT generated by controlled phase shifter 28. Phase detector 12 generates a difference signal DS that represents the phase difference between feedback signal FB and input signal IN. Loop filter 16 filters difference signal DS to generate filtered difference signal FDS. Integrator 22 integrates filtered difference signal FDS to generate a control signal CS. Controlled phase shifter receives a clock signal having a frequency equal to that of input signal IN or a harmonic thereof. Controlled phase shifter 28 operates to generate output signal OUT by delaying clock signal CL by a delay defined by control signal CS generated by integrator 22. Delay-locked loop circuit 20 operates to minimize the difference in phase between input signal IN and feedback signal FB derived from output signal OUT.

FIG. 1C is a block diagram showing an example 30 of a conventional loop filter 16 that constitutes part of phase-locked loop circuit 10 shown in FIG. 1A and part of delay-locked circuit 20 described above with reference to FIG. 1B. Loop filter 16 has a first path 31 and a second path 33 connected to receive difference signal DS. First path 31 is composed of a gain element 32 and a summing element 34 in series. Gain element 32 is connected to receive difference signal DS from phase detector 12 (FIG. 1A) and has an output connected to a first input of summing element 34. Second path 33 is composed of a gain element 36 and an integrator 38 in series. Gain element 36 is connected to receive difference signal DS from phase detector 12 (FIG. 1A). The output of integrator 38 is connected to a second input of summing element 34.

Summing element 34 sums the signals output by gain element 32 and integrator 38 to generate control signal CS (FIG. 1A) or filtered difference signal FDS (FIG. 1B).

Conventionally, phase-locked loop circuits have been implemented using analog circuit elements for phase comparator 12, loop filter 16 and either controlled oscillator 18 or integrator 22 and controlled phase-shifter 28. Such analog circuit elements are subject to offset errors that create problems at times when input signal IN is devoid of transitions. No phase information is available under such input signal conditions, and offsets in the analog circuit elements that function to measure and store phase information cause a false difference signal. The false difference signal in turn leads to phase drift. If the rate of phase drift is large enough, or the time that the input signal is without transitions is long enough, then the phase can change so much that the phase-locked loop circuit loses phase lock by the time the transitions resume. Output signal OUT cannot be used to perform reliable data recovery until phase lock is re-established.

Some mitigation of offset errors is obtained by interposing an analog-to-digital converter (not shown) between phase detector 12 and loop filter 16, and implementing loop filter 16 and either controlled oscillator 18 or integrator 22 and controlled phase-shifter 28 digitally. However, even with such digital implementation, the phase-locked loop circuit still has an analog phase detector that is subject to an offset error. Moreover, the analog portion of the analog-to-digital converter may additionally contribute to the offset error.

What is needed, therefore, is a way of mitigating offset error in the analog circuit elements of a phase-locked loop circuit having a digital loop filter.

### BRIEF DESCRIPTION OF THE DRAWINGS

FIG. 1A is a block diagram showing an example of a conventional phase-locked loop circuit.

FIG. 1B is a block diagram showing an example of another type of conventional phase-locked loop circuit known as a delay-locked loop circuit.

FIG. 1C is a block diagram showing an example of a conventional loop filter that constitutes part of phase-locked circuits shown in FIGS. 1A and 1B.

FIG. 2 is a block diagram showing an example of a phase-locked loop circuit in accordance with an embodiment of the invention.

FIGS. 3-5 are block diagrams showing part of other examples of the phase-locked loop circuit shown in FIG. 2.

FIGS. 6-8 are block diagrams showing other examples of the digital offset mitigation circuit that constitutes part of the phase-locked loop circuit shown in FIG. 5.

FIGS. 9-11 are block diagrams showing ways of inputting the offset correction to the analog section in the example of the phase-locked loop circuit shown in FIG. 2.

### DETAILED DESCRIPTION

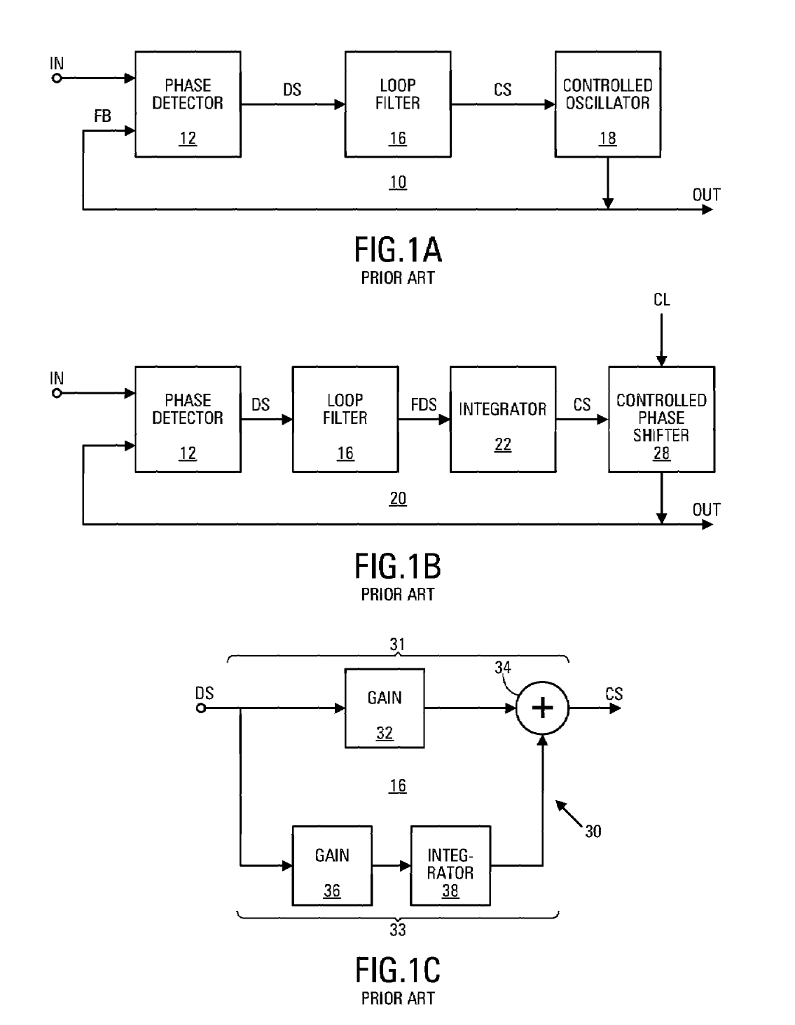

When both types of phase-locked loop circuit described above with reference to FIGS. 1A and 1B are implemented mainly using digital circuitry, imperfections in the remaining analog circuit elements of the phase-locked loop circuit still give rise to an offset error that leads to an error in the measurement of the phase difference between input signal IN and feedback signal FB. When the phase-locked loop is locked to the input signal, the offset error will create a static phase offset. Typically, it is feasible to make the offset error small enough so that the phase offset is negligible in normal operation.

When input signal IN has no transitions, no phase information is available. Under these conditions, the level of difference signal DS input to loop filter 16 relative to the level of difference signal DS corresponding to a phase difference of zero between input signal IN and feedback signal FB should be zero. In a practical phase-locked loop circuit, loop filter 16 comprises an integrator. For example, loop filter 16 described above with reference to FIG. 1C comprises integrator 38.

When the level of difference signal DS input to loop filter 16 is zero, the output of the loop filter, and consequently the phase of output signal OUT, does not change. However, an offset error in the analog circuit elements causes a persistent small difference signal DS to be input to loop filter 16 when there are no transitions in input signal IN. Integrator 38 in loop filter 16 will convert such persistent, small difference signal DS into a persistent change in control signal CS input to controlled oscillator 18 or to controlled phase-shifter 28. In time, the persistent change in control signal CS will destroy the phase alignment between input signal IN and feedback signal FB, and phase-locked loop circuit 10 will lose lock between output signal OUT and input signal IN.

In accordance with an embodiment of the invention, the time that elapses before the phase-locked loop circuit loses lock between output signal OUT and input signal IN is greatly extended by mitigating the offset error of the phase-locked loop circuit. The offset error mitigation can be performed while the phase-locked loop circuit is operating in a set-up mode. Additionally or alternatively, the offset error mitigation can be performed while the phase-locked loop circuit is operating in its normal operating mode. Such offset error mitigation requires a measure of the offset error. The inventors have realized that the persistent, small difference signal DS input to the digital loop filter as a result of the offset error looks exactly like a persistent frequency offset between input signal IN and feedback signal FB. The digital loop filter comprises circuitry capable of measuring and correcting frequency offsets between input signal IN and feedback signal FB. Thus, in accordance with embodiments of the invention, at least part of the second path of the digital loop filter is used to provide such measure the offset error to a digital offset mitigation circuit. The digital offset mitigation circuit then generates an offset correction that mitigates the offset error of the analog section. The offset correction can be a digital offset correction or an analog offset correction.

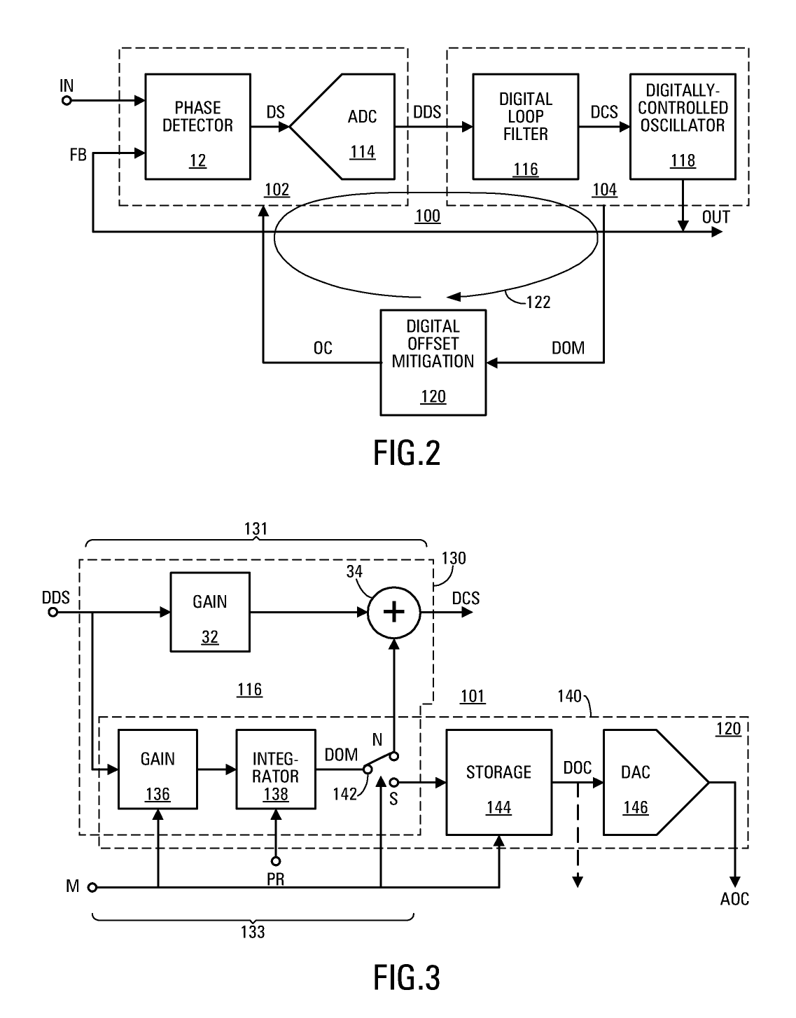

FIG. 2 is a block diagram showing an example of a phase-locked loop circuit 100 in accordance with an embodiment of the invention. Phase-locked loop circuit 100 is composed of an analog section 102, a digital section 104 and a digital offset mitigation circuit 120. Analog section 102 is subject to offset error and comprises mainly analog circuitry. In the example shown, analog section 102 is composed of analog phase detector 12 and an analog-to-digital converter 114 connected in series. Digital section 104 comprises mainly digital circuitry. In the example shown, digital circuitry 104 is composed of a digital loop filter 116 and a digitally-controlled oscillator 118 connected in series.

In analog section 102, analog phase detector 12 is connected to receive an input signal IN at one input and a feedback signal FB at another input. Feedback signal FB is derived from output signal OUT generated by digitally-controlled oscillator 118. Phase detector 12 generates an analog difference signal DS that represents the phase difference between feedback signal FB and input signal IN. Analog-to-digital converter 114 converts analog difference signal DS to a digital difference signal DDS. The offset error of analog section 102 constitutes a component of digital difference signal DDS.

In digital section 104, digital loop filter 116 receives digital difference signal DDS from analog-to-digital converter 114 and filters the digital difference signal DDS to generate a digital control signal DCS that controls the frequency of digitally-controlled oscillator 118 and, hence, the frequency of output signal OUT. Phase-locked loop circuit 100 operates to minimize the difference in phase between output signal OUT generated by digitally-controlled oscillator 118 and input signal IN.

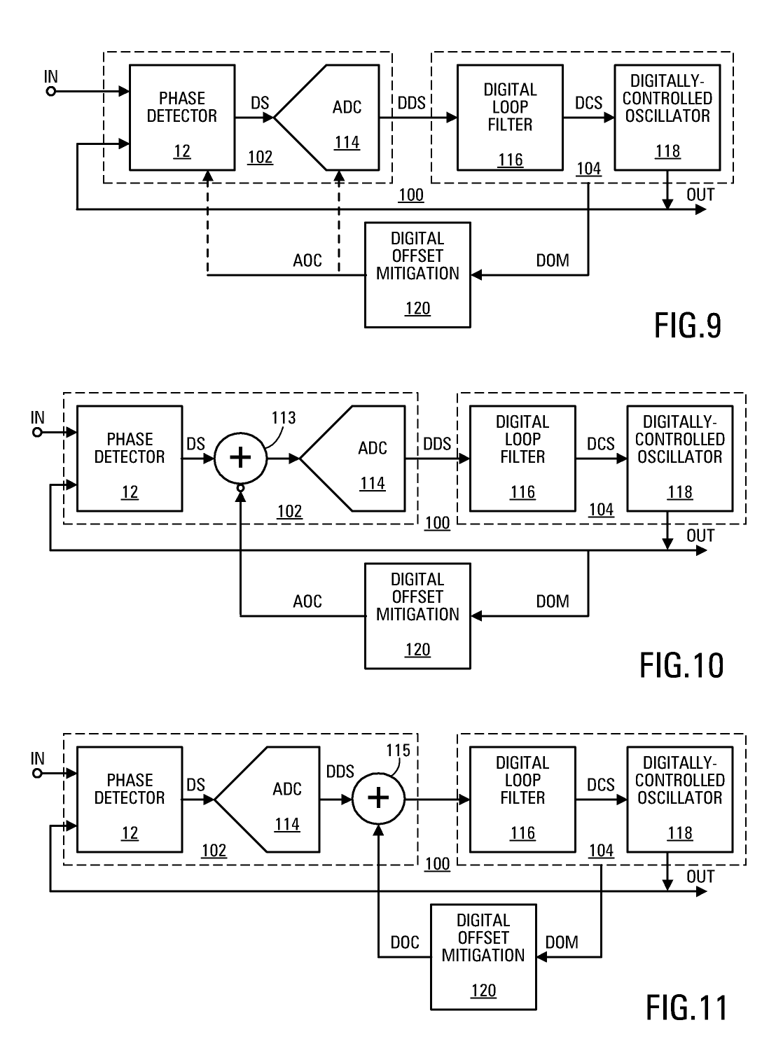

Digital offset mitigation circuit 120 receives a digital offset measurement DOM from digital section 104. Digital offset measurement DOM provides a measure of the offset error of analog section 102. In response to such digital offset measurement DOM, digital offset mitigation circuit 120 provides an offset correction OC to analog section 102. Offset correction OC mitigates the offset error of analog section 102. Typically, offset correction OC is an analog level that is combined with the analog signal at an appropriate location in analog section 102, as will be described in more detail below with reference to FIGS. 9 and 10. Alternatively, offset correction OC is a digital value that is combined with digital difference signal DDS prior to digital loop filter 116, as will be described in more detail below with reference to FIG. 11. Regardless of whether offset correction OC is analog or digital, the sense of the combination is such that the offset correction cancels most if not all of the offset error that constitutes part of digital difference signal DDS. The term offset correction OC is used in this disclosure as a generic term to refer to a digital offset correction DOC or an analog offset correction AOC.

Digital offset mitigation circuit 120, part of analog section 102 and part of digital section 104 collectively constitute an offset mitigation loop 122 that mitigates the offset error of phase-locked loop circuit 100. The part of analog section 102 extends between the point at which offset correction OC is combined and the output of the analog section. The part of digital section 104 extends between the input of digital section 104 and the point where digital offset measurement DOM is output.

A delay-lock loop circuit having a topology similar to that described above with reference to FIG. 1B may also be modified to incorporate an analog-to-digital converter similar to analog-to-digital converter 114, a digital loop filter similar to digital loop filter 116, a digital integrator, a digitally-controlled phase shifter and digital error mitigation circuit 120. The term phase-locked loop circuit as used in this disclosure additionally encompasses such delay-lock loop circuit.

Examples of phase-locked loop circuit 100 will now be described in greater detail with reference to examples in which offset correction OC output by digital offset mitigation circuit 120 is an analog offset correction AOC. Each of the examples of digital offset mitigation circuit 120 described below generates a digital offset correction DOC and uses a digital-to-analog converter to convert the digital offset correction to analog offset correction AOC. In other examples of phase-locked loop circuit 100 that will not be separately described, digital offset mitigation circuit 120 outputs digital offset correction DOC to analog section 102 to mitigate the offset error of the analog section. In such examples, the digital-to-analog converter is omitted from digital offset mitigation circuit 120, and the digital offset mitigation circuit outputs digital offset correction DOC instead of analog offset correction AOC to analog section 102.

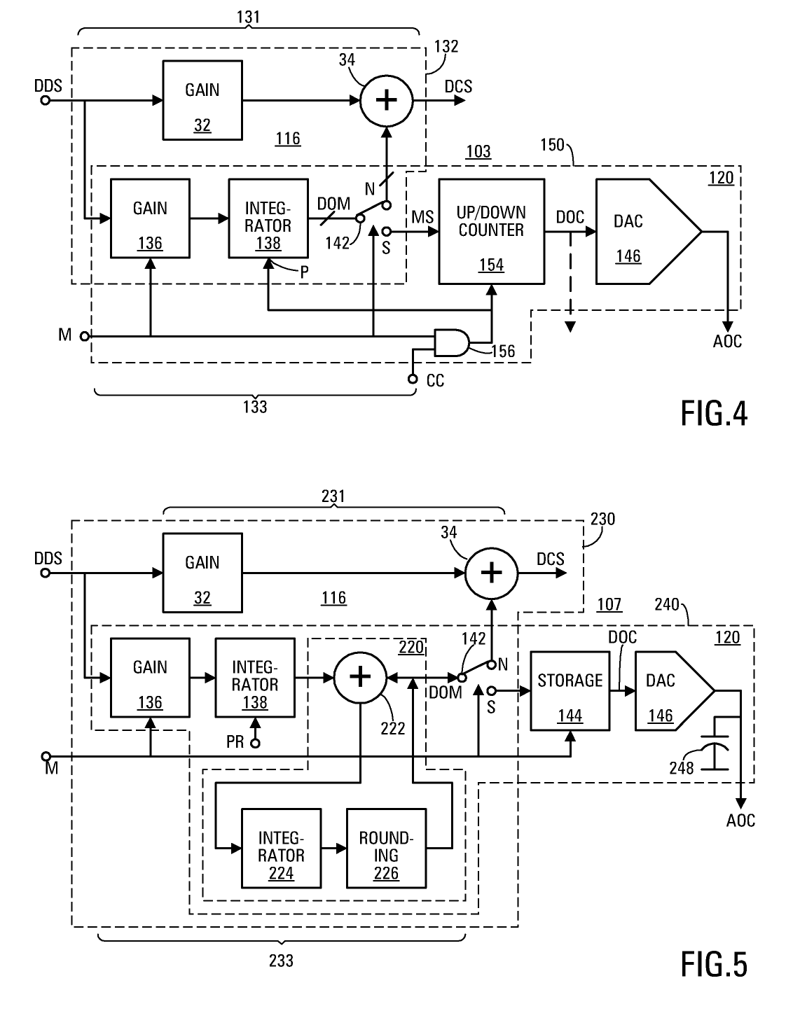

FIG. 3 is a block diagram showing part of an example 101 of phase-locked loop circuit 100 in more detail. In this example, part of digital loop filter 116 is used to generate digital offset measurement DOM that is input to digital offset mitigation circuit 120 as a measure of the offset error of analog section 102. FIG. 3 shows an embodiment 130 of digital loop filter 116 and an embodiment 140 of digital offset mitigation circuit 120 that collectively constitute part of phase-locked loop circuit 101. To simplify the drawing, analog section 102 and digitally-controlled oscillator 118 are omitted from FIG. 3, but are identical to corresponding elements of the example of phase-locked loop circuit 100 shown in FIG. 2. Similar omissions are made from FIGS. 4-8, described below.

Phase-locked loop circuit 101 has two operational modes set by the state of a mode control signal M. In a normal state of the mode control signal, phase-locked loop circuit 101 has a normal operational mode. In a set-up state of the mode control signal, phase-locked loop circuit 101 has a set-up operational mode.

Digital loop filter 130 is similar in structure to a digital implementation of conventional loop filter 30 described above with reference to FIG. 1C. Elements of digital loop filter 130 that correspond to such digital implementation of conventional loop filter 30 are indicated using the same reference numerals and will not be described again in detail. Digital loop filter 130 is composed of a first path 131 and a second path 133 each connected to receive digital difference signal DDS from analog section 102 (FIG. 2). All the elements of digital loop filter 130 are digital elements. First path 131 is composed of gain element 32 and summing element 34 connected in series. The input of gain element 32 is connected to receive digital difference signal DDS from analog section 102 (FIG. 2). The output of gain element 32 is connected to the first input of summing element 34. The output of summing element 34 provides digital control signal DCS to digitally-controlled oscillator 118 (FIG. 2).

Second path 133 is composed of a gain element 136 and an integrator 138 connected in series.

Gain element 136 is a variable-gain element having a gain determined by the state of mode control signal M. In the normal state of the mode control signal, gain element 136 has a gain equal to or similar to that of gain element 36 in conventional loop filter 30 described above with reference to FIG. 1C. Such gain will be referred to as the normal gain of gain element 136. In the set-up state of the mode control signal, gain element 136 has a set-up gain that may be different from the normal gain. Typically the set-up gain is substantially lower than the normal gain.

Integrator 138 is a presettable integrator in which a momentarily-applied preset control signal PR sets the output of the integrator to a predetermined value. The input of gain element 136 is connected to receive digital difference signal DDS from analog-to-digital converter 114. The output of integrator 138 is connected to the second input of summing element 34.

Digital offset mitigation circuit 140 is composed of the second path 133 of digital loop filter 130, a controlled change-over switch 142, a storage element 144 and a digital-to-analog converter 146. The elements of digital offset mitigation circuit 140 are digital elements except for the analog portion of digital-to-analog converter 146. Controlled switch 142 has a common terminal, a first terminal (marked N) and a second terminal (marked S). The common terminal is connected to the output of integrator 138. The first terminal is connected to the second input of summing element 34. The second terminal is connected to the input of storage element 144. Mode control signal M determines the switching state of controlled switch 142. In the normal state of the mode control signal, controlled switch 142 connects the output of integrator 138 to the second input of summing element 34. In this state of the mode control signal, the structure of digital loop filter 130 is similar to that of a digital implementation of conventional loop filter 30 described above with reference to FIG. 1C. In the set-up state of the mode control signal, controlled switch 142 connects the output of integrator 138 to the input of storage element 144.

Storage element 144 is a small digital memory having a capacity sufficient to store digital offset correction DOC. Storage element 144 may be multi-word random access memory or a single-value register. In the example shown, storage element 144 is a programmable memory that allows the offset correction to be calibrated when phase-locked loop circuit 101 is put into service and from time-to-time thereafter. Such programmable memory may be non-volatile so that it retains digital offset correction DOC in the event that phase-locked loop circuit 101 is deliberately or accidentally powered down.

Storage element 144 has two operational modes selected by the state of mode control signal M. The set-up state of the mode control signal sets storage element 144 to a set-up mode in which it receives successive values of digital offset measurement DOM from integrator 138 via switch 142 and stores the most-recently received value of digital offset measurement DOM as digital offset correction DOC. In the set-up mode of storage element, each new digital offset measurement DOM received at the input of storage element 144 overwrites the digital offset correction DOC stored therein to provide a new digital offset correction DOC. The normal state of mode control signal M sets storage element 144 to a normal mode in which the above-described overwriting process is suspended so that the last digital offset measurement DOM received when the mode control signal was in its set-up state remains stored in storage element 144 as digital offset correction DOC. Regardless of the state of the mode control signal, storage element 144 outputs the digital offset correction DOC currently stored therein.

The input of digital-to-analog converter 146 is connected to receive digital offset correction DOC from the output of storage element 144. Digital-to-analog converter 146 converts digital offset correction DOC to analog offset correction AOC and outputs analog offset correction AOC to analog section 102.

The offset error of the analog section 102 of phase-locked loop circuit 101 is mitigated by applying a set-up test signal devoid of transitions to phase comparator 12 (FIG. 2) as input signal IN, setting mode control signal M to its set-up state, and momentarily asserting preset control signal PR to initialize the output of integrator 138 to a predetermined value. The set-up state of mode control signal M sets controlled switch 142 to connect digital offset measurement DOM output by integrator 138 to the input of storage element 144. The set-up state of mode control signal M additionally sets storage element 144 to its set-up mode in which the value of digital offset correction DOC stored therein is overwritten by each new value of digital offset measurement DOM received from integrator 138. Finally, the set-up state of mode control signal M sets gain element 136 to its set-up gain. The set-up gain of gain element 136 provides offset mitigation loop 122 (FIG. 2) comprising digital offset mitigation circuit 140 with sufficient loop gain while ensuring that offset mitigation loop 122 remains stable.

The set-up test signal devoid of transitions input to phase comparator 12 as input signal IN is typically a DC level corresponding to the high state or the low state of a normal input signal. The predetermined value to which preset control signal PR initializes digital offset measurement DOM output by integrator 138 is typically equal to that the value of digital offset measurement DOM output by integrator 138 when output signal OUT matches input signal IN in phase and frequency. Alternatively, the predetermined value can be equal to the value of digital offset measurement DOM that causes digital offset mitigation circuit 140 to output analog output signal AOC at a level that provides no mitigation of the offset error of analog section 102.

Due to the offset error of analog section 102, the value of digital difference signal DDS input to digital loop filter 130 is different from the value of digital difference signal DDS that corresponds to feedback signal FB (FIG. 2) matching input signal IN in phase. Consequently, after initialization, the value of digital offset measurement DOM output by integrator 138 progressively changes in response to the non-zero value of digital difference signal DDS and causes a corresponding change in the value of digital offset correction DOC output by storage element 144. Digital-to-analog converter 146 converts each value of digital offset correction DOC to a corresponding level of analog offset correction AOC. Digital offset mitigation circuit 140 outputs analog offset correction AOC to analog section 102. Analog offset correction AOC mitigates the offset error of analog section 102, which counteracts the change in digital offset measurement DOM.

Analog offset correction AOC eventually settles to a level corresponding to an optimum mitigation of the offset error of analog section 102. The level to which the analog offset correction settles is subject to a small, repetitive fluctuation because digital offset correction DOC from which it is derived dithers between two adjacent values when the offset error mitigation is optimum. Once this occurs, mode control signal M is restored to its normal state. The normal state of mode control signal M sets controlled switch 142 to connect the output of integrator 138 to the second input of summing element 34. Additionally, the normal state of mode control signal M sets gain element 136 to its normal gain, and restores storage element 144 to its normal mode. In its normal mode, storage element 144 outputs the final value of digital offset correction DOC stored therein while mode control signal M was in its set-up state, and analog-to-digital converter 146 continues to convert this value of digital offset correction DOC to analog offset correction AOC. Consequently, analog section 102 continues to receive from digital offset mitigation circuit 140 analog offset correction AOC at a level equal to that which provided the optimum offset error mitigation in the set-up process. With mode control signal M in its normal state, phase-locked loop circuit 101 operates as a normal phase-locked loop circuit, but the mitigation of the offset error of analog section 102 means that phase-locked loop circuit 101 can tolerate longer periods of input signal IN having no transitions without losing lock.

Phase-locked loop circuit 101 may be configured such that offset mitigation loop 122 operates continuously in the background. Such background operation is advantageous when the offset error of analog section 102 is variable. For example, the offset error may depend on an environmental variable, such as temperature. In such configuration, summing element 34, switch 142, storage element 144 and mode control signal M are omitted. The output of gain element 32 provides the digital control signal DCS output by digital loop filter 116, and the output of integrator 138 provides digital offset correction DOC that is input to digital-to-analog converter 146, as described above. Gain element 136 has a fixed gain corresponding to the set-up gain of gain element 136 described above. In this background operating mode, the range of loop dynamics that digital loop filter 130 can provide is restricted because the second path 133 of the digital loop filter is used to provide offset error mitigation.

FIG. 4 is a block diagram showing part of another example 103 of phase-locked loop circuit 100 in more detail. In this example, an up-down counter is used as the storage element in digital offset mitigation circuit 120. As in the example described above with reference to FIG. 3, part of digital loop filter 116 provides a digital offset measurement DOM to digital offset mitigation circuit 120 as a measure of the offset error of analog section 102. FIG. 4 shows an embodiment 132 of digital loop filter 116 and an embodiment 150 of digital offset mitigation circuit 120 that collectively constitute part of phase-locked loop circuit 103. The remainder of phase-locked loop circuit 103 is identical to the example of phase-locked loop circuit 100 shown in FIG. 2. Elements of phase-locked loop circuit 103 that correspond to elements of phase-locked loop circuit 101 described above with reference to FIG. 3 are indicated using the same reference numerals and will not be described again in detail.

Digital loop filter 132 is composed of first path 131 and second path 133 each connected to receive digital difference signal DDS. First path is composed of gain element 32 and summing element 34 connected in series. The input of gain element 32 is connected to receive digital difference signal DDS from analog section 102 (FIG. 2). The output of gain element 32 is connected to the first input of summing element 34. The output of summing element 34 provides digital control signal DCS to digitally-controlled oscillator 118 (FIG. 2).

Second path 133 is composed of gain element 136 and integrator 138 connected in series. The input of gain element 136 is connected to receive digital difference signal DDS from analog-to-digital converter 114 (FIG. 2). The output of integrator 138 is connected to the second input of summing element 34.

Offset mitigation circuit 150 is composed of the second path 133 of digital loop filter 132, controlled switch 142, a storage element composed of an up/down counter 154, a gate 156 and digital-to-analog converter 146. Up-down counter 154 has an input, a count clock input and an output. Gate 156 has a first input, a second input and an output.

The common terminal of switch 142 is connected to the output of integrator 138. The first terminal (marked N) of switch 142 is connected to the second input of summing element 34. The second terminal (marked S) of switch 142 is connected to the input of up-down counter 154 to provide only the sign bit MS of digital offset measurement DOM thereto. The output of up/down counter 154 is connected to the input of digital-to-analog converter 146. The count clock input of up/down counter 154 and the preset input P of integrator 138 are connected to the output of gate 156. The first input of gate 156 is connected to receive mode control signal M. The second input of gate 156 is connected to receive a count clock signal CC.

The state of mode control signal M determines the gain of gain element 136 and the switching state of controlled switch 142, as described above. The state of mode control signal M additionally determines the operation of integrator 138 and the operation of up/down counter 154. In the set-up state of the mode control signal, gate 156 allows count clock signal CC to pass to the preset input P of integrator 138 and to the count clock input of up/down counter 154. Consequently, integrator 138 is preset to a predetermined value each cycle of count clock signal CC. Up/down counter 154 generates digital offset correction DOC by counting up or counting down in response to count clock signal CC. The direction of count of up/down counter 154, i.e., whether up/down counter 154 counts up or counts down, depends on the state of the sign bit MS of digital offset measurement DOM. The normal state of the mode control signal isolates count clock signal CC from the preset input P of integrator 138 and from the count clock input of up/down counter 154. Consequently, integrator 138 operates normally, and up/down counter 154 holds the last value of digital offset correction DOC generated while mode control signal M was in its set-up state. This value of the digital offset correction is the value that provides optimum offset error mitigation. Digital-to-analog converter 146 converts digital offset correction DOC to analog offset correction AOC that digital offset mitigation circuit 150 outputs to analog section 102 (FIG. 2), as described above.

The frequency of count clock signal CC determines the effective loop gain of the offset mitigation loop 122 of which digital offset mitigation circuit 150 constitutes part: a lower frequency reduces the loop gain. The loop gain of offset mitigation loop 122 may additionally or alternatively be determined by making the bit width of up-down counter 154 greater than that of digital-to-analog converter 146. In this case, only the Q most-significant bits of the values of digital offset correction DOC generated by up/down counter 154 are input to digital-to-analog converter 146, where Q is the bit width of the digital-to-analog converter. The set-up gain of gain element 136, the frequency of the count clock signal CC and the relationship between the bit widths of up-down counter 154 and digital-to-analog converter 146 are chosen to provide offset mitigation loop 122 with an adequate loop gain while maintaining the offset mitigation loop 122 stable.

In some embodiments, up/down counter 154 additionally has a preset input (not shown) connected to receive preset signal PR. Momentary application of preset signal PR to such preset input initializes digital offset correction DOC output by up/down counter 154 to a preset value, such as one that provides no mitigation of the offset error of analog section 102.

The offset error of the analog section 102 of phase-locked loop circuit 103 is mitigated by applying a set-up test signal devoid of transitions to phase comparator 12 (FIG. 2) as input signal IN, and setting mode control signal M to its set-up state, as described above. The set-up state of mode control signal M sets gain element 136 to its set-up gain, and sets controlled switch 142 to connect the sign bit MS of digital offset measurement DOM output by integrator 138 to the input of up/down counter 154. Additionally, the set-up state of mode control signal M sets gate 156 to pass count clock signal CC to the preset input P of integrator 138 and to the count clock input of up/down counter 154. Count clock signal CC applied to the preset input of integrator repetitively sets the digital offset measurement DOM generated by integrator 138 to a predetermined value. Consequently, after each transition of count clock signal CC, the sign of the average amplified value of digital difference signal DDS output by gain element 136 since the previous transition of CC determines the sign bit MS of digital offset measurement DOM output by integrator 138. The output of up/down counter 154 may additionally be preset to a preset state by preset control signal PR as described above, or in some other way.

Due to the offset error of analog section 102, the value of digital difference signal DDS input to digital loop filter 130 is different from that of digital difference signal DDS corresponding to output signal OUT matching input signal IN in phase. Consequently, the sign of the value of digital offset measurement DOM output by integrator 138 depends on the sign of the average value of digital difference signal DDS during the previous period of count clock signal CC. In each period of count clock signal CC, the value of digital offset correction DOC output by up/down counter 154 increases or decreases by one, depending on sign bit MS. Consequently, the value of digital offset correction DOC increases in magnitude, and the level of analog offset correction AOC applied to analog section 102 similarly increases in magnitude. Analog offset correction OC applied to analog section 102 mitigates the offset error of analog section 102 until digital offset measurement DOM output by integrator 138 changes in sign, so that sign bit MS changes state. Sign bit MS in its opposite state reverses the direction in which up/down counter 154 counts. Hence, the value of digital offset correction DOC and the level of analog offset correction AOC decrease in magnitude. After one or more iterations, the level of analog offset correction AOC converges on one that provides an optimum offset error mitigation. In this state, digital offset correction DOC alternates in value by one least-significant bit (LSB) about the optimum value, where the LSB is the LSB of DAC 146.

Once analog offset correction AOC has settled to a level corresponding to an optimum mitigation of the offset error of analog section 102, mode control signal M is restored to its normal state. The normal state of mode control signal M causes controlled switch 142 to connect the output of integrator 138 to the second input of summing element 34, as described above, and opens gate 156. Opening gate 156 disconnects count clock signal CC from the preset input of integrator 138 and the count clock input of up/down counter 154. With no count clock signal CC applied to its preset input, integrator 138 operates normally. With no count clock signal applied to its count clock input, up/down counter 154 outputs a value of digital offset correction DOC that remains unchanged until the set-up process is run again.

With mode control signal M in its normal state, up/down counter 154 continues to provide digital offset correction DOC to digital-to-analog converter 146 and digital-to-analog converter 146 continues to convert the digital offset correction to analog offset correction AOC for output to analog section 102. Consequently, analog section 102 continues to receive from digital offset mitigation circuit 150 analog offset correction AOC at a level equal to that which provided the optimum offset error mitigation in the set-up process. With mode control signal M in its normal state, phase-locked loop circuit 103 operates as a normal phase-locked loop circuit, but the mitigation of the offset error of analog section 102 means that phase-locked loop circuit 103 can tolerate longer periods of input signal IN having no transitions without losing lock.

Because the loop gain of offset mitigation loop 122 of which digital offset mitigation circuit 150 constitutes part can be set independently of the loop gain of phase-locked loop circuit 103 by a suitable choice of either or both of the frequency of count clock signal CC and the relationship between the bit widths of up/down counter 154 and digital-to-analog converter 146, digital offset mitigation circuit 150 can be configured to provide continuous offset error mitigation. In such an embodiment, controlled switch 142, gate 156 and mode control signal M are omitted. The output of integrator 138 is connected to the second input of summing element 34, and the most-significant bit of digital offset measurement DOM output by integrator 138 is additionally connected to the input of up/down counter 154. Count clock signal CC is connected directly to the count clock input of up/down counter 154. The frequency of count clock signal CC and the above-described bit width relationship are chosen to provide the offset mitigation loop 122 of which digital offset mitigation circuit 150 constitutes part with sufficient loop gain while ensuring that offset mitigation loop 122 remains stable. But as stated above, in the continuous background operating mode, the range of loop dynamics that digital loop filter 132 can provide is limited.

As noted above, the loop gain of offset mitigation loop 122 (FIG. 2) depends on the frequency of count clock signal CC and the relationship between the bit widths of up-down counter 154 and digital-to-analog converter 146 in addition to the set-up gain of gain element 136. Since the loop gain of the offset mitigation loop can be determined independently of the gain of gain element 136, a fixed gain element similar to gain element 36 described above with reference to FIG. 1C can be used instead of variable gain element 136. In this case, the gain of the gain element is optimized for operation of phase-locked loop circuit 103 in its normal operating mode.

FIG. 5 is a block diagram showing part of another example 107 of phase-locked loop circuit 100 in accordance with an embodiment of the invention. In phase-locked loop circuit 107, digital loop filter 116 incorporates a delta-sigma modulator that enhances its resolution. Phase-locked loop circuit 107 comprises an embodiment 230 of digital loop filter 116 and an embodiment 240 of digital offset mitigation circuit 120.

Digital loop filter 230 is composed of a first path 231 and a second path 233 each connected to receive digital difference signal DDS from analog-to-digital converter 114 (FIG. 2). First path 231 is composed of gain element 32 and summing element 34 connected in series. The input of gain element 32 is connected to receive digital difference signal DDS from analog-to-digital converter 114. The output of gain element 32 is connected to the first input of summing element 34. The output of summing element 34 provides digital control signal DCS to digitally-controlled oscillator 118 (FIG. 2).

Second path 233 is composed of gain element 136, integrator 138 and a delta-sigma modulator 220 connected in series. The example of delta-sigma modulator 220 shown is a first-order delta-sigma modulator and is composed of a two-input summing element 222, an integrator 224 and a rounding element 226. The output of integrator 138 is connected to a first input of summing element 222. Integrator 224 and rounding element 226 are connected in series between the output of summing element 222 and the second input of summing element 222. The output of rounding element 226 is additionally connected to the second input of summing element 34. A higher-order delta-sigma modulator may alternatively be used as delta-sigma modulator 220.

Digital offset mitigation circuit 240 is composed of the second path 233 of digital loop filter 230, controlled switch 142, storage element 144, digital-to-analog converter 146 and integrating capacitor 248. The elements of digital offset mitigation circuit 240 are digital elements except for integrating capacitor 248 and the analog portion of digital-to-analog converter 246.

The common terminal of controlled switch 142 is connected to the output of the rounding element 226 of delta-sigma modulator 220. The first terminal (marked N) of controlled switch 142 is connected to the second input of summing element 34. The second terminal (marked S) of controlled switch 142 is connected to the input of storage element 144. The state of mode control signal M determines the gain state of gain element 136, the switching state of controlled switch 142, and the mode of storage element 144, as described above.

Digital-to-analog converter 146 and integrating capacitor 248 collectively generate analog offset correction AOC from digital offset correction DOC output by storage element 144. Analog offset correction AOC is input to analog section 102 (FIG. 2).

The offset error of the analog section 102 of phase-locked loop circuit 107 is mitigated by applying a set-up test signal devoid of transitions to phase comparator 12 (FIG. 2) as input signal IN, setting mode control signal M to its set-up state, and momentarily asserting preset control signal PR to initialize the output of integrator 138 to a predetermined value, as described above. The set-up state of mode control signal M sets gain element 136 to its set-up gain and sets controlled switch 142 to connect the output of rounding element 226 to the input of storage element 144. In this state of controlled switch 142, rounding element 226 supplies digital offset measurement DOM to the input of storage element 144. The set-up state of mode control signal M additionally sets storage element 144 to its set-up mode, as described above, so that storage element 144 stores the most-recently received value of digital offset measurement DOM as digital offset correction DOC and additionally outputs the stored digital offset correction.

Digital offset mitigation circuit 240 generates analog offset correction AOC that mitigates the offset error of phase-locked loop circuit 107. When analog offset correction AOC eventually settles to a level corresponding to an optimum mitigation of the offset error of analog section 102, digital offset measurement DOM output by delta-sigma modulator 222 and, hence, digital offset correction DOC output by storage element 144, alternate between two values. Digital-to-analog converter 146 converts the alternating values of digital offset correction DOC to an alternating analog signal that alternates between two levels corresponding to the alternating values of the digital offset correction. Integrating capacitor 248 integrates such alternating analog signal to generate analog offset correction AOC as a steady DC level intermediate between the levels of the alternating analog signal. The level of analog offset correction AOC depends on the values between which digital offset correction DOC alternates and the duty cycle of the alternation.

Because analog offset correction AOC is intermediate between two analog levels that correspond to respective values of digital offset correction DOC, it is capable of providing a more optimum mitigation of the offset error of phase-locked loop circuit 107 than if its level corresponded to one value of digital offset correction DOC, as in the embodiments described above with reference to FIGS. 3 and 4.

After analog offset correction AOC has settled to a level corresponding to an optimum mitigation of the offset error of analog section 102, mode control signal M is restored to its normal state. In the normal state of mode control signal M, controlled switch 142 connects the output of delta-sigma modulator 220 to the second input of summing element 34, and storage element 144 is restored to its normal mode in which it outputs the last value of digital offset measurement DOM it received while mode control M was in its set-up state. Since storage element 144 outputs only one of the two values between which digital offset correction DOC alternated when phase-locked loop circuit 107 was in its set-up operating mode, the greater effectiveness of the offset error mitigation obtained when phase-locked loop circuit 107 was in its set-up operating mode is lost when phase-locked loop circuit 107 is restored to its normal operating mode. The offset error mitigation obtained in the normal operating mode of phase-locked loop circuit 107 can differ from the optimum offset error mitigation by an offset mitigation amount that can be as much as the offset mitigation amount that corresponds to one least-significant bit of digital offset correction DOC.

As noted above, digital offset correction DOC alternates between the two values with a duty cycle that determines the optimum offset error mitigation. Consequently, except when the duty cycle is 50%, one value of the digital offset correction can be said to predominate over the other. The value that predominates will be called the predominant value. The change in offset error mitigation that occurs when phase-locked loop circuit 107 is restored to its normal operating mode can be reduced to an offset mitigation amount no more than the offset mitigation amount that corresponds to one-half of the least-significant bit of the digital offset correction by storing the predominant value of digital offset measurement DOM in storage element 144 when phase-locked loop circuit 107 is restored to its normal operating mode. This way, the predominant value of the digital offset correction is output from storage element 144 when phase-locked loop circuit 107 is restored to its normal operating mode.

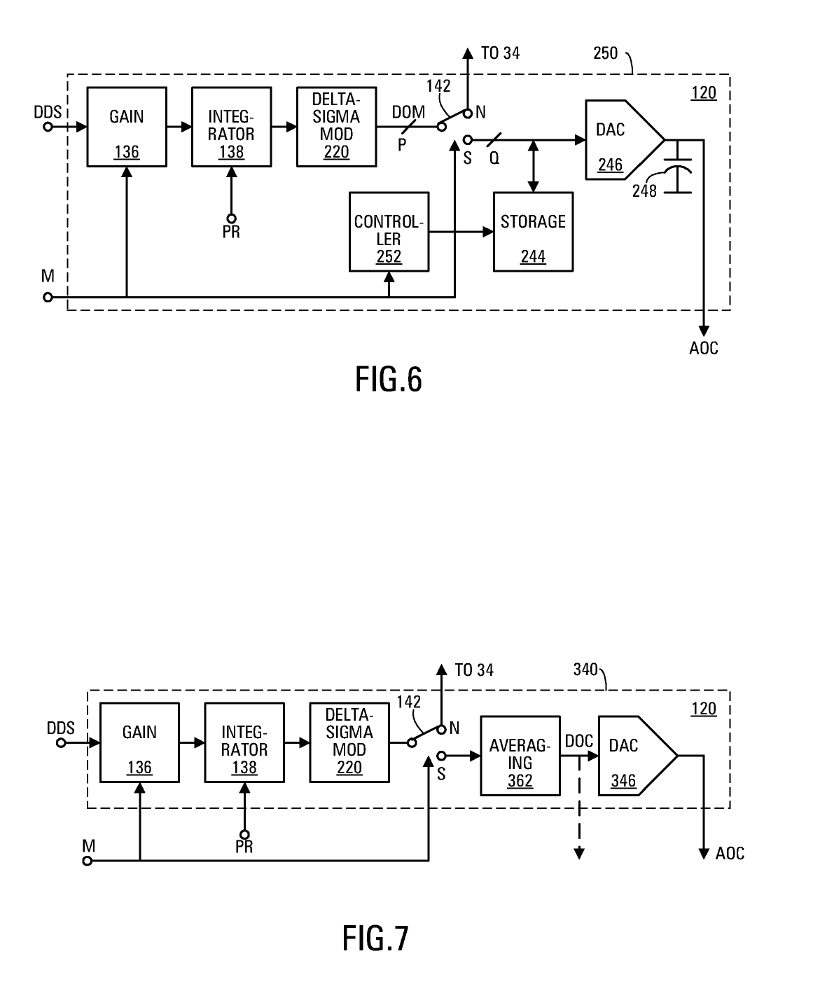

FIG. 6 is a block diagram showing another example 250 of digital offset mitigation circuit 120 comprising a delta-sigma modulator in which optimum offset error mitigation is maintained when phase-locked loop circuit 107 is restored to its normal operating mode. Additionally, this example uses a low-resolution digital-to-analog converter whose bit width is narrower than that of the digital circuitry of phase-locked loop circuit 107. Such a digital-to-analog converter is substantially lower in cost than one having a bit width equal to that of the digital circuitry of phase-locked loop circuit 107.

Digital offset mitigation circuit 250 is similar in structure to digital offset mitigation circuit 240 described above with reference to FIG. 5, but a multi-value storage element 244 and a memory controller 252 are substituted for single-value storage element 144, and a low-resolution digital-to-analog converter 246 is substituted for medium-resolution digital-to-analog converter 146. Storage element 244 and digital-to-analog converter 246 have a bit width Q that is substantially narrower than the bit width P of the digital loop filter 116 (FIG. 5) and the remaining digital portions of phase-locked loop circuit 107.

Storage element 244 has an input/output port and a control input. Storage element 244 has a sequential write mode and a sequential read mode determined by a control signals provided to its control input by controller 252. The input/output port of storage element 244 is connected to the second terminal S of switch 142. In the write mode of storage element 244, the input/output port receives the Q most significant bits of successive values of digital offset measurement DOM output by delta-sigma modulator 220. The input/output port is additionally connected to the input of digital-to-analog converter 246. In the read mode of storage element 244, the input/output port outputs successive values of digital offset correction DOC stored in storage element 244 to digital-to-analog converter 246. Controller 252 additionally has a control input connected to receive mode control signal M. Integrating capacitor 248 is connected to the output of digital-to-analog converter 246. Digital-to-analog converter 246 outputs analog offset correction AOC to analog section 102 (FIG. 2).

The offset error of the analog section 102 of phase-locked loop circuit 107 is mitigated by applying a set-up test signal devoid of transitions to phase comparator 12 (FIG. 2) as input signal IN, setting mode control signal M to its set-up state, and momentarily asserting preset control signal PR to initialize the output of integrator 138 to a predetermined value, as described above. The set-up state of mode control signal M sets controlled switch 142 to connect the output of delta-sigma modulator 220 to the input of digital-to-analog converter 246 and to the input/output port of storage element 244. Digital offset mitigation circuit 250 generates analog offset correction AOC that mitigates the offset error of phase-locked loop circuit 107. Once analog offset correction AOC settles to a level corresponding to an optimum mitigation of the offset error of analog section 102, digital offset measurement DOM output by delta-sigma modulator 220 alternates between two values. Digital-to-analog converter 246 converts the Q most significant bits of digital offset measurement DOM to an alternating analog signal that alternates between two levels corresponding to the alternating values of digital offset measurement DOM. Integrating capacitor 248 integrates such analog signal to generate analog offset correction AOC as a steady DC level intermediate between the levels of the alternating analog signal. The level of analog offset correction AOC depends on the values between which digital offset measurement DOM alternates and the duty cycle of the alternation. Because analog offset correction AOC is intermediate between the two analog levels that correspond to respective values of digital offset measurement DOM, it is capable of providing a more optimum mitigation of the offset error of phase-locked loop circuit 107 than if its level corresponded to one value of digital offset measurement DOM, as in the embodiments described above with reference to FIGS. 3 and 4.

Mode control signal M in its set-up state additionally sets controller 262 to cause storage element 244 to store the 2^{N} successive values of digital offset measurement DOM most-recently received from delta-sigma modulator 220 via switch 142 as respective values of digital offset correction DOC. A newly-received value of digital offset measurement DOM overwrites the oldest value of digital offset correction DOC stored in storage element 244. N is the difference between P and Q, i.e., N=P−Q.

After analog offset correction AOC has settled to the level corresponding to an optimum mitigation of the offset error of analog section 102, mode control signal M is restored to its normal state. The normal state of mode control signal M sets controlled switch 142 to connect the output of delta-sigma modulator 220 to the second input of summing element 34. Additionally, the normal state of mode control signal M sets controller 262 to cause storage element 244 to sequentially output the 2^{N} values of digital offset correction DOC stored therein to digital-to-analog converter 246. Digital-to-analog converter 246 converts the sequence of 2^{N} values of digital offset correction DOC to an alternating analog signal that alternates between two levels corresponding to the levels of digital offset correction DOC. Integrating capacitor 248 integrates the alternating analog signal to generate analog offset correction AOC at a level identical to that generated when phase-locked loop circuit 107 was in its set-up mode.

In typical implementations, the cost of multi-value storage element 244, controller 252 and low-resolution digital-to-analog converter 246 is substantially less than that of single-value storage element 144 and medium-resolution digital-to-analog converter 146 notwithstanding the additional capacity of storage element 244 and the addition of controller 252. In one example, digital loop filter 116 had a 25-bit bit width and digital-to-analog converter 246 had a 6-bit input bit width.

In another configuration, controller 252 is interposed between storage element 244 and the connection between controlled switch 142 and digital-to-analog converter 246. Controller 252 and storage element 244 each have a bit width equal to the bit width of digital-to-analog converter 246, i.e., Q bits, and the values of digital offset measurement DOM input to storage element 244 and controller 252 are truncated to its Q bits in this embodiment. The set-up state of mode control signal M sets controller 252 to a set-up mode in which it causes storage element 244 to store each unique value in the 2^{N} successive values of digital offset measurement DOM most recently received from delta-sigma modulator 220. Additionally, controller 252 additionally causes storage element 244 to store an occurrence value for each of the unique values stored therein. The occurrence value indicates the number of occurrences of the unique value in the 2^{N} successive values. The unique values and their respective occurrence values collectively constitute digital offset correction DOC. The normal state of mode control signal M sets controller 254 to a normal state in which it causes storage element 244 to output to digital-to-analog converter 246 a sequence of 2^{N} values in which occurrence of each of the unique values stored in storage element 244 is determined by the respective recurrence value. A randomizing technique is typically used to prevent long runs of the same unique value. This technique allows storage element 244 to be substantially reduced in size compared with the storage element in the above-described embodiment in which the storage element stores all 2^{N} values. Storage element 244 is integrated with controller 252 in some implementations.

FIG. 7 is a block diagram showing an example 340 of digital offset mitigation circuit 120 that uses a digital averaging circuit and a high-resolution digital-to-analog converter to reduce the loss of optimum offset error mitigation when phase-locked loop circuit 107 is restored to its normal operating mode.

Digital offset mitigation circuit 340 is similar in structure to digital offset mitigation circuit 240 described above with reference to FIG. 5, but a digital averaging circuit 362 and a high-resolution digital-to-analog converter 346 connected in series are substituted for storage element 144, medium-resolution digital-to-analog converter 146 and integrating capacitor 248. When mode control signal M is in its set-up state, digital averaging circuit 362 averages successive values of digital offset measurement DOM received from delta-sigma modulator 220 to generate digital offset correction DOC. The bit width of digital offset correction DOC generated by averaging circuit 362 and the bit width of digital-to-analog converter 346 are greater than the bit width of the digital circuitry of phase-locked loop circuit 107. The greater resolution of digital offset correction DOC and, hence, of analog offset correction AOC, provide a more optimum mitigation of the offset error of analog section 102 than that provided by digital offset mitigation circuit 240 described above with reference to FIG. 5.

The input of averaging circuit 362 is connected to the second terminal S of switch 142. Averaging circuit 362 generates digital offset correction DOC for output to digital-to-analog converter 346. Digital-to-analog converter 346 converts digital offset correction DOC to analog offset correction AOC and outputs analog offset correction AOC to analog section 102 (FIG. 2)

When mode signal M is in its setup state, digital offset mitigation circuit 340 operates to generate analog offset correction AOC that is input to analog section 102 to mitigate the offset error of the analog section. When analog offset correction AOC settles to a level that provides an optimum mitigation of the offset error, digital offset measurement DOM output by delta-sigma modulator 220 alternates between two values, as described above. Averaging circuit 362 averages the values of digital offset measurement DOM to generate digital offset correction DOC. The value of digital offset correction DOC output by averaging circuit 362 is intermediate to the values between which digital offset measurement DOM alternates, and depends on the duty cycle of the alternation. Digital-to-analog converter 346 converts digital offset correction DOC to a corresponding level of analog offset correction AOC.

After analog offset correction AOC has settled to the level corresponding to an optimum mitigation of the offset error of analog section 102, mode signal M is returned to its normal state. The normal state of mode control signal M sets controlled switch 142 to connect the output of delta-sigma modulator 220 to the second input of summing element 34. In this state of switch 142, digital offset measurement DOM is no longer input to averaging circuit 362, but averaging circuit 362 continues to output the final value of digital offset correction DOC it generated while mode control signal M was in its set-up state, i.e., the value of digital offset correction DOC that provided optimum offset error mitigation. Thus, in this embodiment, the offset error mitigation does not change when phase-locked loop circuit 107 returns to its normal operating mode. Because digital offset correction DOC is a digital value and analog offset correction AOC is an analog level obtained by converting a digital value, the offset error mitigation provided by digital offset mitigation circuit 340 may be less than that provided by digital offset mitigation circuit 250 described above with reference to FIG. 6. The difference depends on the bit-width of averaging circuit 362 and/or that of digital-to-analog converter 346.

In embodiments of phase-locked loop circuit 107 in which digital loop filter 116 is capable of controlling the phase-locked loop without its second path 233, the various embodiments of digital offset mitigation circuit 120 described above may be configured to provide continuous offset error mitigation in a manner similar to that described above with reference to FIG. 3.

High-resolution digital-to-analog converter 346 has a bit width greater than that of medium-resolution digital-to-analog converter 146 used in the digital offset mitigation circuits shown in FIGS. 3, 4 and 5. As noted above, the cost of a digital-to-analog converter increases significantly with increasing bit width, i.e., with increasing resolution.

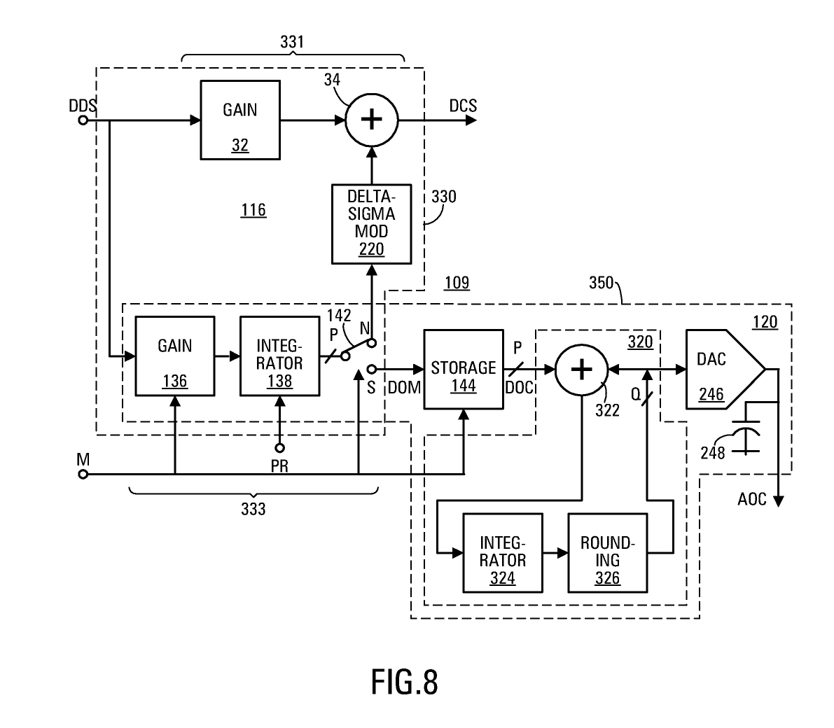

FIG. 8 is a block diagram showing part of another example 109 of phase-locked loop circuit 100 in accordance with an embodiment of the invention. In phase-locked loop circuit 109, an embodiment 330 of digital loop filter 116 incorporates delta-sigma modulator 220 that enhances its resolution and an embodiment 350 of digital offset mitigation circuit 120 incorporates an additional delta-sigma modulator that increases the resolution of the analog offset correction analog offset correction output by the digital offset mitigation circuit and additionally allows a low-resolution digital-to-analog converter to be used.

Digital loop filter 330 is composed of a first path 331 and a second path 333 connected to receive digital difference signal DDS from analog-to-digital converter 114 (FIG. 2). First path 331 is composed of gain element 32 and summing element 34 connected in series. The input of gain element 32 is connected to receive digital difference signal DDS from analog-to-digital converter 114. The output of gain element 32 is connected to the first input of summing element 34. The output of summing element 34 provides digital control signal DCS to digitally-controlled oscillator 118 (FIG. 2).

Second path 333 is composed of gain element 136, integrator 138 and delta-sigma modulator 220 connected in series in an arrangement similar to that described above with reference to FIG. 5, except that the positions of change-over switch 142 and delta-sigma modulator 220 are reversed. The input of gain element 136 is connected to receive digital difference signal DDS from analog-to-digital converter 114. The output of delta-sigma modulator 220 is connected to the second input of summing element 34. Delta-sigma modulator 220 is a first- or higher-order delta-sigma modulator, as described above, and will be referred to as first delta-sigma modulator 220.

Digital offset mitigation circuit 350 is composed of part of the second path 333 of digital loop filter 330, namely, gain element 136 and integrator 138; change-over switch 142; storage element 144; a second delta-sigma modulator 320; low-resolution digital-to-analog converter 246 and integrating capacitor 248. The common terminal of change-over switch 142 is connected to the output of integrator 138. The first terminal, marked N, of change-over switch 142 is connected to the input of first delta-sigma modulator 220. The second terminal, marked S, of change-over switch 142 is connected to the input of storage element 144. Storage element 144, second delta-sigma modulator 320, digital-to-analog converter 246 and integrating capacitor 248 are connected in series.

The example of second delta-sigma modulator 320 shown is a first-order delta-sigma modulator and is composed of a two-input summing element 322, an integrator 324 and a rounding circuit 326. Summing element 322 has a first input, a second input and an output. The first input is connected to the output of storage element 144 and has a bit-width P equal to that of digital loop filter 330 and storage element 144. Integrator 324 and rounding circuit 326 are connected in series between the output of summing element 322 and the second input of summing element 322. The output of rounding circuit 326 is additionally connected to the input of digital-to-analog converter 246. Rounding circuit 326 rounds the output of integrator 324 to a bit width Q equal to that of digital-to-analog converter 246, and substantially less than that of storage element 144. A higher-order delta-sigma modulator may alternatively be used as second delta-sigma modulator 320.

The offset error of the analog section 102 of phase-locked loop circuit 109 is mitigated by applying a set-up test signal devoid of transitions to phase comparator 12 (FIG. 2) as input signal IN, setting mode control signal M to its set-up state, and momentarily asserting preset control signal PR to initialize the output of integrator 138 to a predetermined value, as described above. The set-up state of mode control signal M sets gain element 136 to its set-up gain and sets controlled switch 142 to connect successive values of digital offset measurement DOM output by integrator 138 to the input of storage element 144. The set-up state of mode control signal M additionally sets storage element 144 to its set-up mode, as described above, so that storage element 144 stores the most-recently received value of digital offset measurement DOM as digital offset correction DOC and additionally outputs the stored digital offset correction.

The bit width P of digital offset correction DOC output by storage element 144 is substantially greater than the bit width Q of digital-to-analog converter 246. However, by using second delta-sigma modulator 320 and integrating capacitor 248 in addition to digital-to-analog converter 246 to generate analog offset correction AOC from digital offset correction DOC, the analog offset correction is generated with a resolution corresponding to the P-bit resolution of digital offset correction DOC notwithstanding the substantially lower bit width of digital-to-analog converter 246. Analog offset correction AOC is input to analog section 102 (FIG. 2), where it mitigates the offset error of phase-locked loop circuit 109.

After analog offset correction AOC has settled to a level corresponding to an optimum mitigation of the offset error of analog section 102, mode control signal M is restored to its normal state. The normal state of mode control signal M restores gain element 136 to its normal gain, restores storage element 144 to its normal mode, and sets controlled switch 142 to connect the output of integrator 138 to the second input of summing element 34 via first delta-sigma modulator 220. First delta-sigma modulator 220 increases the effective resolution of digital loop filter 330 in the normal operating mode of phase-locked loop circuit 109.

With controlled switch 142 connecting the output of integrator 138 to the input of first delta-sigma modulator 220, digital offset measurement DOM is no longer input to storage element 144. However, storage element 144 continues to output the last value of digital offset correction DOC that was stored in storage element 144 while mode control signal M was in its set-up state, i.e., the value of digital offset correction DOC that provided optimum offset error mitigation. Second delta-sigma modulator 320 converts P-bit digital offset correction DOC output by storage element 144 to an alternating Q-bit digital signal that alternates between two adjacent Q-bit values. The Q-bit values and the duty cycle of the alternation depend on the value of digital offset correction DOC. Digital-to-analog converter 246 converts the alternating Q-bit digital signal output by delta-sigma modulator 320 to an alternating analog signal that alternates between two levels that correspond to the alternating values of the Q-bit digital signal. Integrating capacitor 248 integrates such alternating analog signal to generate analog offset correction AOC as a steady DC level intermediate between the levels of the alternating analog signal. The level of analog offset correction AOC depends on the levels of the alternating analog signal output by digital-to-analog converter 246 and the duty cycle of the alternation, and is the same as the level of analog offset correction AOC that provided optimum offset mitigation when mode control signal M was in its set-up state. Thus, digital offset mitigation circuit 350 continues to provide optimum offset error mitigation when phase-locked loop circuit 109 is restored to its normal operating mode.

In embodiments of phase-locked loop circuit 109 in which digital loop filter 116 is capable of controlling the phase-locked loop without its second path 333, first delta-sigma modulator 220 may be omitted, and digital offset mitigation circuit 350 may be configured to provide continuous offset error mitigation in a manner similar to that described above with reference to FIG. 3.

Analog offset correction AOC is described above as being input to analog section 102 to mitigate the offset error of the analog section. FIG. 9 is a block diagram showing analog offset correction AOC output by digital offset mitigation circuit 120 input to analog section 102. In one implementation, analog offset correction AOC is input to a node within analog phase detector 12. The node is typically located downstream of the point in phase detector 12 where a phase difference between input signal IN and feedback signal FB derived from output signal OUT has been converted to an analog signal, i.e., an analog voltage or current. Analog offset correction AOC is combined with the analog signal at the node in such a sense that the analog offset correction attenuates the offset error component in the analog signal.

FIG. 9 additionally shows an alternative implementation in which analog offset correction AOC is input to a node within the analog circuitry of analog-to-digital converter 114. Analog offset correction AOC is combined with the analog signal at the node in such a sense that the analog offset correction attenuates the offset error component in the analog signal.

FIG. 10 is a block diagram showing an example of an alternative arrangement of inputting analog offset correction AOC to analog section 102. An analog summing element 113 is interposed between the output of phase detector 12 and the input of analog-to-digital converter 114. The analog summing element has a first input connected to the output of phase detector 12, a second input connected to receive analog offset correction AOC from the output of digital offset mitigation circuit 120, and an output connected to the input of analog-to-digital converter 114. Analog summing element 113 combines analog offset correction AOC with analog difference signal DS in such a sense that the analog offset correction attenuates the offset error component in difference signal DS.

As noted above, digital offset mitigation circuit 120 may be configured to output digital offset correction DOC instead of analog offset correction AOC. FIG. 11 is a block diagram showing an example of an arrangement for inputting digital offset correction DOC to analog section 102. A digital summing element 115 is interposed between the output of analog-to-digital converter 114 and the input of digital loop filter 116. The digital summing element has a first input connected to receive digital difference signal DDS from the output of analog-to-digital converter 114, a second input connected to receive digital offset correction DOC from the output of digital offset mitigation circuit 120, and an output connected to the input of digital loop filter 116. Digital summing element 116 combines digital offset correction DOC with digital difference signal DDS in such a sense that the digital offset correction attenuates the offset error component in the digital difference signal.

This disclosure describes the invention in detail using illustrative embodiments. However, the invention defined by the appended claims is not limited to the precise embodiments described.

We claim:

1. A phase-locked loop circuit, comprising:
an analog section subject to offset error and comprising an analog phase comparator and an analog-to-digital converter;
a digital section comprising a digital loop filter and a digitally-controlled frequency-generating circuit, the digital loop filter connected to receive a digital difference signal from the analog-to-digital converter; and
a digital offset mitigation circuit operable in response to the digital difference signal to mitigate the offset error of the analog section.

2. The phase-locked loop circuit of claim 1, in which:
the digital loop filter comprises a first path and a second path each connected to receive the digital difference signal, the first path comprising a gain element and a summing element in series, the second path comprising a gain element and an integrator in series, the second path operable to generate values of a digital offset measurement from the digital difference signal; and
the digital offset mitigation circuit comprises at least part of the second path of the digital loop filter.

3. The phase-locked loop circuit of claim 2, in which the digital offset mitigation circuit additionally comprises a storage element operable to store a value of the digital offset measurement and to output the stored value as a digital offset correction.

4. The phase-locked loop circuit of claim 3, in which the digital offset mitigation circuit additionally comprises a digital-to-analog converter connected to receive the digital offset correction from the storage element and operable in response thereto to generate an analog offset correction for output to the analog section.

5. The phase-locked loop circuit of claim 3, in which the analog section additionally comprises a digital summing element operable to combine the digital offset correction with the digital difference signal.

6. The phase-locked loop circuit of claim 3, in which:
the storage element has an input; and
the digital offset mitigation circuit additionally comprises a switch operable to connect the integrator to one of (a) the input of the storage element in a set-up operating mode of the phase-locked loop circuit, and (b) the summing node in a normal operating mode of the phase-locked loop circuit.

7. The phase-locked loop circuit of claim 6, in which the digital offset mitigation circuit additionally comprises a digital-to-analog converter connected to receive the digital offset correction from the storage element and operable in response thereto to generate an analog offset correction for output to the analog section.

8. The phase-locked loop circuit of claim 6, in which the analog section additionally comprises a digital summing element operable to combine the digital offset correction signal with the digital difference signal.

9. The phase-locked loop circuit of claim 2, in which the digital offset mitigation circuit additionally comprises an up/down counter operable to generate a digital offset correction in response to the sign bit of the digital offset measurement and additionally in response to a count clock signal.

10. The phase-locked loop circuit of claim 9, in which the digital offset mitigation circuit additionally comprises a digital-to-analog converter connected to receive the digital offset correction from the up/down counter and operable in response thereto to generate an analog offset correction for output to the analog section.

11. The phase-locked loop circuit of claim 9, in which the analog section additionally comprises a digital summing element operable to combine the digital offset correction with the digital difference signal.

12. The phase-locked loop circuit of claim 9, in which:
the up/down counter has an input; and
the digital offset mitigation circuit additionally comprises a switch operable to connect the integrator to one of (a) the input of the up/down counter in a set-up operating mode of the phase-locked loop circuit, and (b) the summing node in a normal operating mode of the phase-locked loop circuit.

13. The phase-locked loop circuit of claim 12, in which the digital offset mitigation circuit additionally comprises a digital-to-analog converter connected to receive the digital offset correction signal and operable in response thereto to generate an analog offset correction for output to the analog section.

14. The phase-locked loop circuit of claim 12, in which the analog section additionally comprises a digital summing element operable to combine the digital offset correction signal with the digital difference signal.

15. The phase-locked loop circuit of claim 2, in which the second path of the digital loop filter additionally comprises a delta-sigma modulator in series with the gain element and the integrator.

16. The phase-locked loop circuit of claim 15, in which the digital offset mitigation circuit additionally comprises:
a storage element operable to store a value of the digital offset measurement and to output the stored value as a digital offset correction;
a digital-to-analog converter operable to convert the digital offset correction to an analog signal; and
an integrating capacitor operate to integrate the analog signal to generate an analog offset correction.

17. The phase-locked loop circuit of claim 16, in which:
the storage element has an input; and
the digital offset mitigation circuit additionally comprises a switch operable to connect the delta-sigma modulator to (a) the input of the storage element in a set-up operating mode of the phase-locked loop circuit, and (b) the summing node in a normal operating mode of the phase-locked loop circuit.

18. The phase-locked loop circuit of claim 16, in which:
the delta-sigma modulator is a first delta-sigma modulator;
the digital offset mitigation circuit additionally comprises a second delta-sigma modulator interposed between the storage element and the digital-to-analog converter, the second delta-sigma modulator configured to output values substantially narrower in bit width than the digital offset correction; and
the digital-to-analog converter is substantially narrower in bit width than the digital offset correction.

19. The phase-locked loop circuit of claim 18, in which:
the storage element has an input; and
the digital offset mitigation circuit additionally comprises a switch operable to connect the integrator to one of (a) the input of the storage element in the set-up operating mode of the phase-locked loop circuit, and (b) the input of the first delta-sigma modulator in the normal operating mode of the phase-locked loop circuit.

20. The phase-locked loop circuit of claim 15, in which the digital offset mitigation circuit additionally comprises:
a storage element operable in a set-up operating mode of the phase-locked loop circuit to store a predetermined number of the values of the digital offset measurement as respective digital offset correction values, and additionally operable in a normal operating mode of the phase-locked loop circuit to output a sequence of the digital offset correction values;
a digital-to-analog converter operable to convert the sequence of digital offset correction values to an analog signal; and
an integrating capacitor operable to integrate the analog signal to generate an analog offset correction.

21. The phase-locked loop circuit of claim 20, in which:
the storage element has an input/output port; and
the digital offset mitigation circuit additionally comprises a switch operable to connect the delta-sigma modulator to (a) the input/output port of the storage element in the set-up operating mode of the phase-locked loop circuit, and (b) the summing node in the normal operating mode of the phase-locked loop circuit.

22. The phase-locked loop circuit of claim 20, in which the storage element is operable to store each unique one of the digital offset measurement values in the predetermined number of values and, for each unique one of the values, a respective occurrence value, and is operable in response to the unique ones of the digital offset measurement values and the occurrence values to output the sequence of the digital offset correction values.

23. The phase-locked loop circuit of claim 15, in which the digital offset mitigation circuit additionally comprises:
a digital averaging circuit having an input, the averaging circuit operable to average the values of the digital offset measurement to generate a digital offset correction, and additionally operable to output the digital offset correction; and
a digital-to-analog converter operable to convert the digital offset correction to an analog offset correction.

24. The phase-locked loop circuit of claim 23, in which:
the averaging circuit has an input; and
the digital offset mitigation circuit additionally comprises a switch operable to connect the delta-sigma modulator to one of (a) the input of the averaging circuit in the set-up operating mode of the phase-locked loop circuit, and (b) the summing node in the normal operating mode of the phase-locked loop circuit.
